(19) United States
(12) Patent Application Publication
(10) Pub. No.: US 2025/0132153 A1
(43) Pub. Date: Apr. 24, 2025

(54) VAN DER WAALS CONTACT SEMICONDUCTOR DEVICE, AND MANUFACTURING METHOD OF THE SAME

(71) Applicant: AJOU UNIVERSITY INDUSTRY-ACADEMIC COOPERATION FOUNDATION, Suwon-si (KR)

(72) Inventors: Jae-Hyun LEE, Bucheon-si (KR); Soheil GHODS, Suwon-si (KR); Seung-II KIM, Suwon-si (KR)

(73) Assignee: AJOU UNIVERSITY INDUSTRY-ACADEMIC COOPERATION FOUNDATION, Suwon-si (KR)

(21) Appl. No.: 18/910,363

(22) Filed: Oct. 9, 2024

(30) Foreign Application Priority Data
Oct. 10, 2023 (KR) 10-2023-0134553

(51) Int. Cl. H01L 21/02; H10D 62/80; H10D 64/64

(52) U.S. Cl. CPC H01L 21/02568; H01L 21/02527; H10D 62/882; H10D 62/883; H10D 64/64

(57) ABSTRACT

Provided is a manufacturing method of a Van der Waals contact semiconductor device, which includes arranging and patterning a first material on a first substrate; arranging and patterning a second material on a second substrate; and transferring the second material onto the first material, in which any one of the first material and the second material is a topological insulator (TI), and the other one includes a two-dimensional semiconductor material, and the first material and the second material are subjected to Van der Waals contact.

### CROSS-REFERENCE TO RELATED APPLICATION

This application is based on and claims priority under 35 U.S.C. § 119 to Korean Patent Application No. 10-2023-0134553, filed on Oct. 10, 2023, in the Korean Intellectual Property Office, the disclosure of which is incorporated by reference herein in its entirety.

### BACKGROUND

### Field

The present disclosure relates to a Van der Waals contact semiconductor device, and a manufacturing method of the same.

### Description of the Related Art

A semiconductor is an essential part of electronic devices used in most fields such as communications, traffic, energy, research, education, etc., and a demand there of is increasing in an electronic device application field which is rapidly developed. The semiconductor is divided into a P-type semiconductor and an N-type semiconductor according to impurity doping, and when the P-type semiconductor and the N-type semiconductor are bonded, it is possible to manufacture a transistor which may control current.

The P-type transistor and the N-type transistor are also present in the transistor, and development of the P-type transistor has been delayed due to various problems unlike the N-type transistor which has been actively researched. Specifically, metal having a high work function needs to be used as a contact material in order to manufacture the P-type transistor. When the metal having the high work function is used, the height of a short-key barrier which is a potential energy barrier formed at the junction between the metal and the semiconductor may be decreased, making it easier to move a charge carrier. At this time, a physical deposition process is accompanied in order to use the metal as the contact material, and as a result, a defect may be generated in a semiconductor material. The defect generated in the semiconductor material leads Fermi-level pinning, and as a result, a high short-key barrier may be formed, and a feature change of the P-type transistor to the N-type transistor may occur due to such a phenomenon.

As a method for solving this, there is a Van der Waals contact. The Van der Waals contact does not include a deposition process, and the defect of the semiconductor material is not caused, thereby reducing a short-key barrier height. In this regard, the semiconductor material used for the Van der Waals contact may remove a Fermi-level pinning phenomenon, and the short-key barrier height may be reduced, but there is a limit in that a metal-inducted gap state (MIGS) which may be generated between the metal and the semiconductor material may not be completely solved.

A thesis (Liu, H. W.; Zhu, X. L.; Sun, X. X.; Zhu, C. G.; Huang, W.; Zhang, X. H.; Zheng, B. Y.; Lou, Z. X.; Luo, Z. Y.; Wang, X.; Li, D.; Pan, A. L., Self-Powered Broad-band Photodetectors Based on Vertically Stacked WSe2/Bi2Te3 p-n Heterojunctions. ACS Nano, 2019, 13, 13573-13580) which becomes a background of the present disclosure discloses hetero junction of a topological insulator and a two-dimensional semiconductor material, but is formed by deposition.

### SUMMARY

In order to solve the problem in the related art, the present disclosure provides a method for manufacturing a Van der Waals contact semiconductor device by a transfer technique and a Van der Waals contact semiconductor device manufactured through transfer.

However, a technical object to be achieved by the exemplary embodiment of the present disclosure is not limited to the technical objects and there may be other technical objects.

According to an aspect of the present disclosure, there is provided a manufacturing method of a Van der Waals contact semiconductor device, which includes arranging and patterning a first material on a first substrate; arranging and patterning a second material on a second substrate; and transferring the second material onto the first material, in which any one of the first material and the second material is a topological insulator (TI), and the other one includes a two-dimensional semiconductor material, and the first material and the second material are subjected to Van der Waals contact.

According to one implementation embodiment of the present disclosure, the second material may be transferred to be spaced apart from the first material by a Van der Waals gap, but is not limited thereto.

According to one implementation embodiment, the transferring of the second material may include separating the second substrate and the second material; picking up the second material onto a transfer substrate; and dropping down the second material onto the first material, but is not limited thereto.

According to one implementation embodiment, the manufacturing method may further include, before performing the transferring of the second material, transferring the first material onto a third substrate, but is not limited thereto.

According to one implementation embodiment, the transferring of the first material onto the third substrate may include separating the first substrate and the first material; picking up the first material onto a transfer substrate; and dropping down the first material onto the third substrate, but is not limited thereto.

According to one implementation embodiment of the present disclosure, each of the patterning of the first material and the patterning of the second material may independently include an etching process selected from the group consisting of optical etching, wet etching, dry etching, and combinations thereof, but is not limited thereto.

According to one implementation embodiment of the present disclosure, any one of the first material and the second material may include a material selected from the group consisting of Bi₂Se₃, Bi₂Te₃, Sb₂Te₃, and combinations thereof, but is not limited thereto.

According to one implementation embodiment of the present disclosure, the other one of the first material and the second material may include a material selected from the group consisting of doped graphene, transition metal dichalcogenide (TMDC), black phosphorus, and combinations thereof, but is not limited thereto.

According to the second aspect of the present disclosure, there is provided a Van der Waals contact semiconductor device manufactured by the method according to the first aspect.

The above-described task resolution means is only an exemplary, and should not be interpreted as the intention to restrict the present disclosure. In addition to the exemplary embodiments described above, there may be additional exemplary embodiments in drawings and the detailed description of the present disclosure.

Since the Van der Waals contact semiconductor device in the related art is manufactured by a deposition scheme, a direct contact between a Van der Waals material and metal or a two-dimensional semiconductor material is made, which can generate a defect in a Van der Waals material structure, and the direct contact between the Van der Waals material and the metal or the two-dimensional semiconductor material generates a Fermi level pinning effect which can cause a high contact resistance, and a short-key barrier is formed to reduce the performance of the device and a feature of the Van der Waals material can be changed.

However, in a manufacturing method of the Van der Waals contact semiconductor device according to the present disclosure, a Van der Waals contact semiconductor device can be manufactured, in which since the Van der Waals material is transferred onto the two-dimensional semiconductor material or the two-dimensional semiconductor material is transferred onto the Van der Waals material, the Van der Waals material and the two-dimensional semiconductor material are not in direct contact with each other, so a contact resistance is low and structural defect and damage are not generated, and the short-key barrier is lowered.

However, the effects that can be obtained herein are not limited to the effects described above, and there may be another effect.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic view of a Van der Waals contact semiconductor device according to one implementation embodiment of the present disclosure;

FIG. 2 is a schematic view illustrating a manufacturing method of a Van der Waals contact semiconductor device according to one implementation embodiment of the present disclosure;

FIG. 3 is a schematic view illustrating a manufacturing method of a Van der Waals contact semiconductor device according to one implementation embodiment of the present disclosure;

FIG. 4 is a schematic view illustrating a manufacturing method of a Van der Waals contact semiconductor device according to one implementation embodiment of the present disclosure;

FIG. 5 is a schematic view of a Van der Waals contact semiconductor device according to an exemplary embodiment of the present disclosure;

FIG. 6A is a photo acquired by photographing a Van der Waals contact semiconductor device according to an exemplary embodiment of the present disclosure, and FIG. 6B is a photo acquired by photographing a semiconductor device according to one comparative embodiment of the present disclosure; and

FIG. 7A illustrates a short-key barrier height of a Van der Waals contact semiconductor device according to an exemplary embodiment of the present disclosure, and FIG. 7B illustrates a short-key barrier height of a semiconductor device according to one comparative embodiment of the present disclosure.

### DETAILED DESCRIPTION OF THE EMBODIMENT

Hereinafter, exemplary embodiments of the present disclosure will be described in detail so as to be easily implemented by those skilled in the art, with reference to the accompanying drawings.

However, the present disclosure may be implemented in various different forms and is not limited to exemplary embodiments described herein. In addition, in the drawings, in order to clearly describe the present disclosure, a part not related to the description is omitted and like reference numerals designate like elements throughout the present disclosure.

Throughout the specification of the present disclosure, when it is described that a part is “connected” with another part, it means that the certain part may be “directly connected” with another part and the elements “electrically connected” to each other with a third element interposed therebetween as well.

Throughout this specification, it will be understood that when a member is referred to as being “on”, “at an upper portion of”, “on the top of”, “beneath”, “at a lower portion of”, and “on the bottom of” another member, it may be directly on the other member or intervening members may also be present.

Throughout this specification, unless explicitly described to the contrary, a case where any part “includes” any component will be understood to imply the inclusion of stated components but not the exclusion of any other component.

The terms used in the present disclosure, “approximately”, “substantially”, etc. are used in the meaning of the mentioned meaning, when the inherent manufacturing and material allowable error is presented, and is used in the meaning or close to that value, and to help the understanding of the present application, the term is used to prevent unjust use of the disclosure containing accurate or absolute figures for unjust use of unjustly used infringers. Further, throughout the specification of the present disclosure, “step (of˜)” or “step of˜” does not mean “step for”.

Throughout the specification of the present disclosure, the term “combination thereof” included in the expression of the Makushi form means one or more mixed or combination selected from the group consisting of the components described in the expression of the Makushi format, and means including one or more selected from the group consisting of the components.

Throughout the specification of the present disclosure, the disclosure of “A and/or B” means “A or B, or A and B”.

Hereinafter, a Van der Waals contact semiconductor device and a manufacturing method of the same will be described in detail with reference to implementation embodiments and exemplary embodiments, and drawings. However, the present disclosure is not limited to the implementation embodiments and the exemplary embodiments, and the drawings.

A first aspect of the present disclosure relates to a manufacturing method of a Van der Waals contact semiconductor device, which includes arranging and patterning a first material on a first substrate; arranging and patterning a second material on a second substrate; and transferring the second material onto the first material, in which any one of the first material and the second material is a topological insulator (TI), and the other one includes a two-dimensional semiconductor material, and the first material and the second material are subjected to Van der Waals contact.

The topological insulator according to the present disclosure means an insulator in which current does not flow inside a material, but current flows on a surface (a boundary of the material). Since the topological insulator has a surface having electrical conductivity in spite of the insulator, the topological insulator may have a valence band and a conduction band because electrons actively move, so the topological insulator may be utilized for the semiconductor device.

The Van der Waals contact means that atoms are in contact with each other while attraction and repulsion are balanced when another force is not present.

According to one implementation embodiment of the present disclosure, the second material may be transferred to be spaced apart from the first material by a Van der Waals gap, but is not limited thereto.

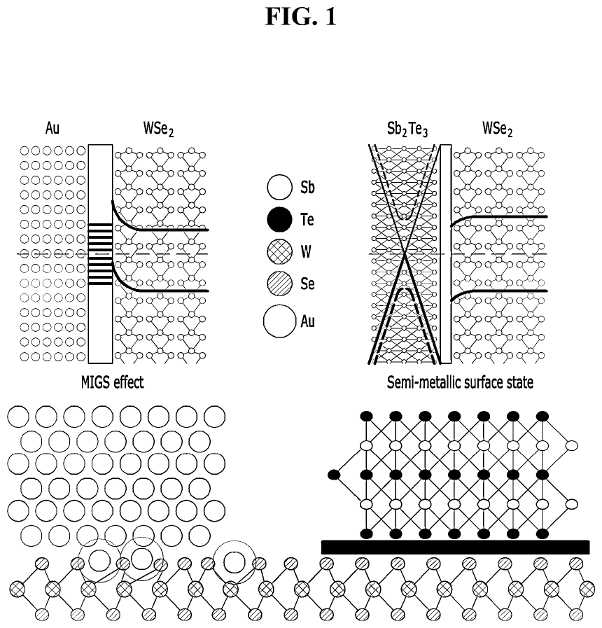

FIG. 1 is a schematic view of a Van der Waals contact semiconductor device according to one implementation embodiment of the present disclosure. Specifically, a left side of FIG. 1 is a conventional Van der Waals device in which metal is deposited on a topological insulator, and a right side of FIG. 1 is a Van der Waals device according to the present disclosure, in which a two-dimensional semiconductor material (transition metal dichalcogenide) is transferred onto the topological insulator.

Referring to FIG. 1, in the conventional Van der Waals device, since metal (Au) is deposited on a topological insulator (WSe2), some of metallic atoms damage the surface of the topological insulator on an interface between the metal and the topological insulator, which may damage a physical property of the topological insulator. However, in the Van der Waals device according to the present disclosure, since the topological insulator and the two-dimensional semiconductor are spaced apart from each other by a Van der Waals gap, and subjected to Van der Waals contact, the surface of the topological insulator is not damaged.

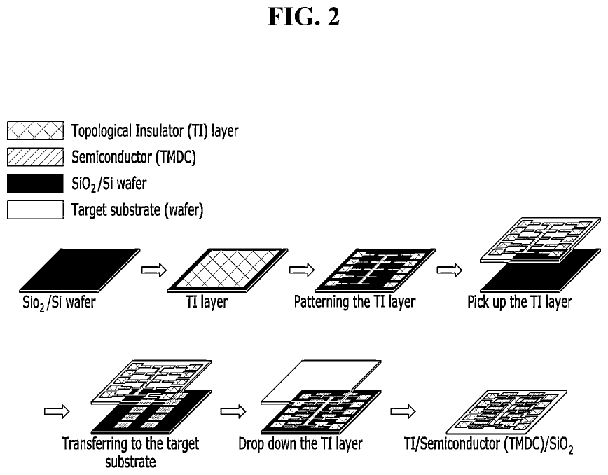

FIGS. 2 to 4 are schematic views illustrating a manufacturing method of a Van der Waals contact semiconductor device according to one implementation embodiment of the present disclosure.

First, a first material is arranged and patterned on a first substrate.

Meanwhile, a second material is arranged and patterned on a second substrate.

According to one implementation embodiment of the present disclosure, any one of the first material and the second material may include a material selected from the group consisting of Bi₂Se₃, Bi₂Te₃, Sb₂Te₃, and combinations thereof, but is not limited thereto.

According to one implementation embodiment of the present disclosure, the other one of the first material and the second material may include a material selected from the group consisting of doped graphene, transition metal dichalcogenide (TMDC), black phosphorus, and combinations thereof, but is not limited thereto.

When any one of the first material and the second material, for example, the first material is the topological insulator, the second material may be the two-dimensional semiconductor material. Alternatively, when any one of the first material and the second material, for example, the first material is the two-dimensional semiconductor material, the second material may be the topological insulator.

Subsequently, the second material is transferred onto the first material.

In the Van der Waals device according to the present disclosure, the topological insulator and the two-dimensional semiconductor material are subjected to the Van der Waals contact, and the two-dimensional semiconductor material is transferred onto the topological insulator or the topological insulator is transferred onto the two-dimensional semiconductor material to manufacture the Van der Waals device. That is, the other one is transferred onto any one of the first material and the second material to manufacture the Van der Waals device according to the present disclosure.

According to one implementation embodiment, the transferring of the second material may include separating the second substrate and the second material; picking up the second material onto a transfer substrate; and dropping down the second material onto the first material, but is not limited thereto.

When the second material is separated from the second substrate, and the transfer substrate and the second substrate are bonded, the second material may be moved. Subsequently, when the second material is arranged on the first material by using the transfer substrate, and the transfer substrate is removed, the second material may be dropped down onto the first material.

Referring to FIG. 2, when the first material is the two-dimensional semiconductor material (for example, TMDC) and the second material is the topological insulator material (TI), the TI may be arranged on the Si wafer, and patterned, and then the Si wafer and the TI may be separated, and then the TI may be transferred onto the patterned TMDC.

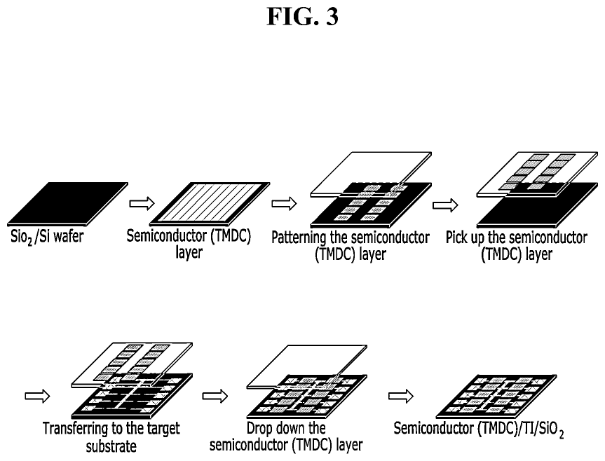

Referring to FIG. 3, when the second material is the two-dimensional semiconductor material (for example, TMDC) and the first material is the topological insulator material (TI), the TMDC may be arranged on the Si wafer, and patterned, and then the Si wafer and the TMDC may be separated, and then the TMDC may be transferred onto the patterned TI.

According to one implementation embodiment of the present disclosure, the dropping down of the second material may be performed at 70° C. to 110° C., but is not limited thereto.

Specifically, in the transferring of the second material onto the transfer substrate, first, a PPC (or PC)/PDMS/glass structure transfer substrate may be manufactured, and subsequently, when the TMDC or TI is contacted with, and then separated from the transfer substrate heated at 50° C. to 90° C., a TMDC or TI layer may be transferred onto the transfer substrate. Subsequently, the transfer substrate onto which the TMDC or TI is transferred is arranged on the TI or TMDC of the first substrate, and a temperature is adjusted to 70° C. to 110° C., and then the transfer substrate and the first substrate are separated to drop down the second material onto the first material.

According to one implementation embodiment, before performing the transferring of the second material, transferring the first material onto a third substrate may be additionally included, but the present disclosure is not limited thereto.

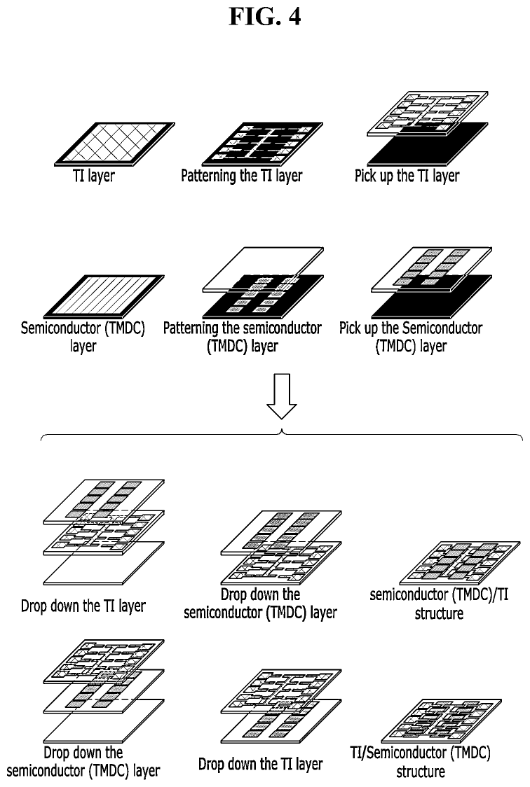

FIG. 4 expresses both a method for transferring the second material onto the first material and a method for transferring the first material onto the second material in order to manufacture the Van der Waals contact semiconductor device.

According to one implementation embodiment of the present disclosure, the transferring of the first material onto the third substrate may include separating the first substrate and the first material; picking up the first material onto the transfer substrate; and dropping down the first material onto the third substrate, but is not limited thereto.

According to one implementation embodiment of the present disclosure, each of the patterning of the first material and the patterning of the second material may independently include an etching process selected from the group consisting of optical etching, wet etching, dry etching, and combinations thereof, but is not limited thereto.

Further, a second aspect of the present disclosure relates to the Van der Waals contact semiconductor device manufactured by the method according to the first aspect.

As described above, in the Van der Waals contact semiconductor device according to the present disclosure, the topological insulator is transferred onto the two-dimensional semiconductor material or the two-dimensional semiconductor material is transferred onto the topological insulator, so the two-dimensional semiconductor material and the topological insulator are subjected to the Van der Waals contact. As a result, as described above, a problem which may occur due to deposition may not occur.

In the Van der Waals contact semiconductor device according to the present disclosure, for example, the two-dimensional semiconductor material is transferred onto the topological insulator, and the topological insulator and the two-dimensional semiconductor material are spaced apart from each other by the Van der Waals gap, a Fermi level pinning effect may not occur, but the height of the short-key barrier may be reduced.

Hereinafter, the present disclosure intends to be described in more detail through embodiments, but the following embodiments are just for the purpose of the description, and does not intend to limit the scope of the present disclosure.

### EMBODIMENTS

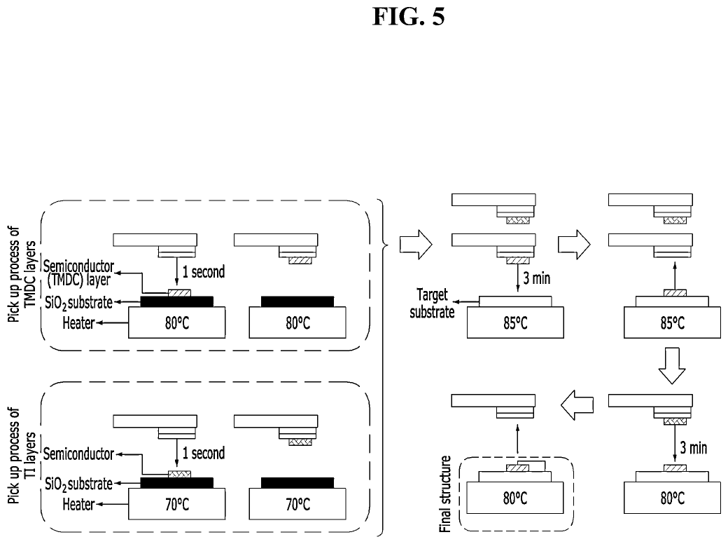

FIG. 5 is a schematic view of a Van der Waals contact semiconductor device according to an exemplary embodiment of the present disclosure.

First, a PDMS was dropped onto a glass substrate, and arranged in an oven at 80° C. for 24 hours to enhance bonding force and stability with glass. Subsequently, in order to arrange a PPC (or PC) on the PDMS, the PDMS was plasma-treated with 10 sccm O₂ gas, 10 minutes, and power of 10 W. Subsequently, the PPC was coated on the PDMS at a speed of 2500 rpm to 3000 rpm, and PPC/PDMS/glass was heat-treated at 80° C. for 30 minutes to manufacture a transfer substrate.

Further, WSe₂ or Sb₂Te₃ was arranged on the glass substrate, and heated at 60° C. to 80° C. Subsequently, the transfer substrate was made to be in contact with WSe₂ or Sb₂Te₃ arranged on the glass substrate, and picked up, and heat-treated at 80° C.

Subsequently, the substrate in which Sb₂Te₃ or WSe₂ was arranged was heated at 80° C. to 100° C., the picked-up WSe₂ or Sb₂Te₃ was made to be contacted on the Sb₂Te₃ or WSe₂, and maintained for 3 minutes, and then immerged in an organic solvent such as anisol for 2 minutes to remove impurities. Subsequently, the substrate was washed by using acetone, ethanol, DI water, etc., to manufacture the Van der Waals contact semiconductor device.

### COMPARATIVE EMBODIMENT

Au was deposited on WSe₂.

### Experimental Embodiment 1

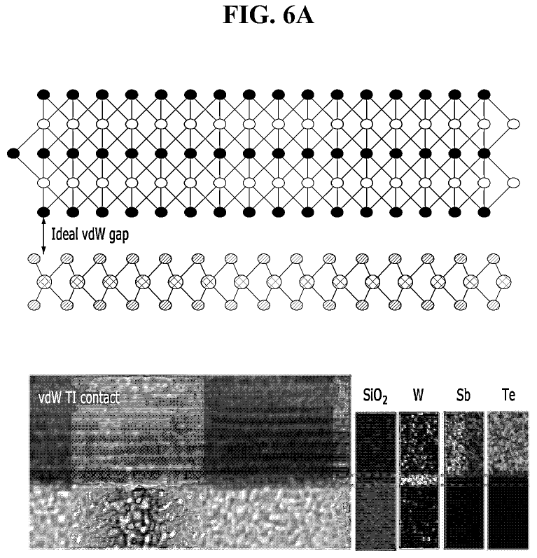

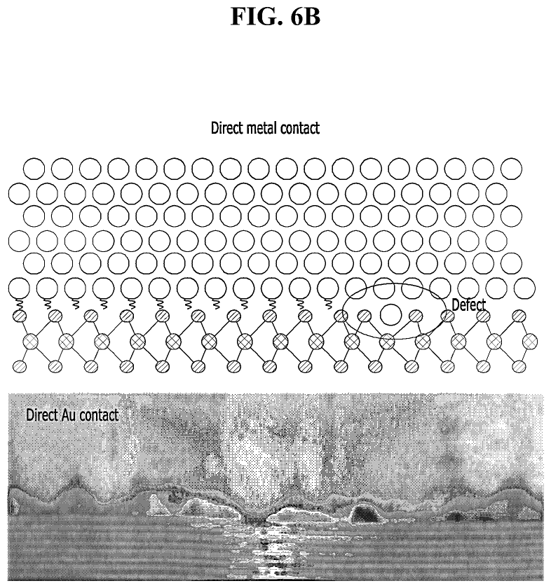

FIG. 6A is a photo acquired by photographing a Van der Waals contact semiconductor device according to an exemplary embodiment of the present disclosure, and FIG. 6B is a photo acquired by photographing a Van der Waals contact semiconductor device according to one comparative embodiment of the present disclosure. Specifically, FIG. 6A illustrates that Sb₂Te₃ is transferred onto a WSe₂ substrate (Sb₂Te₃/WSe₂), and FIG. 6B illustrates that Au is directly deposited onto the WSe₂ substrate, and manufactured (Au/WSe₂).

Referring to FIGS. 6A and 6B, in the case of Au/WSe₂, a part of a structure of WSe₂ may be damaged by Au deposited during a manufacturing process (defect), in the case of Sb₂Te₃/WSe₂, there is a Van der Waals gap between Sb₂Te₃ and WSe₂, so structural damage of WSe₂ and Sb₂Te₃ does not occur.

### Experimental Embodiment 2

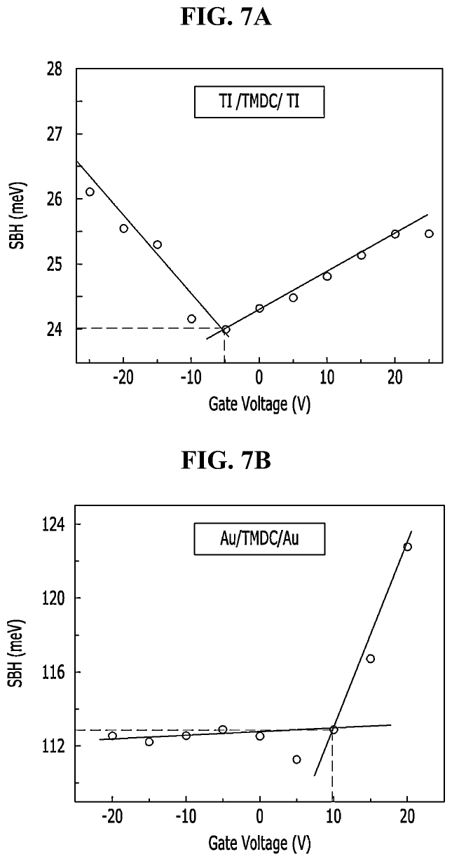

FIG. 7A illustrates a short-key barrier height of a Van der Waals contact semiconductor device according to an exemplary embodiment of the present disclosure, and FIG. 7B illustrates a short-key barrier height of a semiconductor device according to one comparative embodiment of the present disclosure.

Referring to FIG. 7A, the contact between the TMDC and the TI may have low contact resistance and Fermi level pinning because the short-key barrier is low. However, when the TMDC and the Au are directly deposited, the short-key barrier is high, which interferes with movement of electrons, and as a result, high contact resistance and Fermi level pinning may occur.

The aforementioned description of the present disclosure is used for exemplification, and it may be understood by those skilled in the art that the present disclosure may be easily modified in other detailed forms without changing the technical spirit or requisite features of the present disclosure. Therefore, it should be appreciated that the aforementioned embodiments are illustrative in all aspects and are not restricted. For example, respective constituent elements described as single types may be distributed and implemented, and similarly, constituent elements described to be distributed may also be implemented in a coupled form.

The scope of the present disclosure is represented by claims to be described below rather than the detailed description, and it is to be interpreted that the meaning and scope of the claims and all the changes or modified forms derived from the equivalents thereof come within the scope of the present disclosure.

What is claimed is:

1. A manufacturing method of a Van der Waals contact semiconductor device, comprising:
Arranging and patterning material on a first substrate;
arranging and patterning a second material on a second substrate; and
transferring the second material onto the first material,
wherein any one of the first material and the second material is a topological insulator (TI), and the other one includes a two-dimensional semiconductor material, and
the first material and the second material are subjected to Van der Waals contact.

2. The manufacturing method according to claim 1, wherein the second material is transferred to be spaced apart from the first material by a Van der Waals gap.

3. The manufacturing method according to claim 1, wherein the transferring of the second material includes separating the second substrate and the second material; picking up the second material onto a transfer substrate; and dropping down the second material onto the first material.

4. The manufacturing method according to claim 3, wherein the dropping down of the second material is performed at 70° C. to 110° C.

5. The manufacturing method according to claim 1, further comprising:
before performing the transferring of the second material,
transferring the first material onto a third substrate.

6. The manufacturing method according to claim 5, wherein the transferring of the first material onto the third substrate includes separating the first substrate and the first material; picking up the first material onto a transfer substrate; and dropping down the first material onto the third substrate.

7. The manufacturing method according to claim 1, wherein each of the patterning of the first material and the patterning of the second material independently includes an etching process selected from the group consisting of optical etching, wet etching, dry etching, and combinations thereof.

8. The manufacturing method according to claim 1, wherein any one of the first material and the second material includes a material selected from the group consisting of Bi₂Se₃, Bi₂Te₃, Sb₂Te₃, and combinations thereof.

9. The manufacturing method according to claim 1, wherein the other one of the first material and the second material includes a material selected from the group consisting of doped graphene, transition metal dichalcogenide (TMDC), black phosphorus, and combinations thereof.

10. A Van der Waals contact semiconductor device manufactured by a method according to claim 1.
